(19) United States
(12) Patent Application Publication
(10) Pub. No.: US 2005/0127523 A1
(43) Pub. Date: Jun. 16, 2005

(54) Semiconductor device, method of manufacturing semiconductor device, semiconductor chip, electronic module and electronic equipment

(76) Inventor: Tatsuhiro Urushido, Sakata-shi (JP)

Correspondence Address: HARNESS, DICKEY & PIERCE, P.L.C., P.O. BOX 828, BLOOMFIELD HILLS, MI, 48303, US

(21) Appl. No.: 11/009,989

(22) Filed: Dec. 10, 2004

(30) Foreign Application Priority Data
Dec. 12, 2003 (JP) 2003-414831

(51) Int. Cl. H01L 23/48

(52) U.S. Cl. 257/773; 257/786

(57) ABSTRACT

A semiconductor device is provided. At least two second group electrodes are located in each of a plurality of regions partitioned by a plurality of second lines orthogonalized with a first line. Each of the regions is a region surrounded by a pair of the second lines contacting and sandwiching a pair of first group electrodes adjacent to each other. The thus formed semiconductor chip is mounted on a substrate such that the first group electrodes face leads of the first group and the second group electrodes face the leads of the second group. Each lead of the second group is located so as to go through the leads of the first group.

### RELATED APPLICATIONS

This application claims priority to Japanese Patent Application No. 2003-414831 filed Dec. 12, 2003 which is hereby expressly incorporated by reference herein in its entirety.

### BACKGROUND

1. Technical Field

The present invention relates a semiconductor device, a method of manufacturing a semiconductor device, a semiconductor chip, an electronic module and an electronic apparatus.

2. Related Art

In a fabrication such as chip-on film (COF), an electrode of a semiconductor chip is electrically connected to a lead. In recent years, a pitch of electrodes becomes narrower and a pitch of leads also has to be narrowed corresponding to it. However, in consideration of error in alignment of electrodes with leads, narrowing a pitch is limited. When a pitch of electrodes of a semiconductor chip is narrow, it is difficult to avoid contacting a lead with an electrode adjacent to the electrode jointed with the lead.

The present invention is intended to avoid contacting a lead with an electrode.

### SUMMARY

A semiconductor device of the present invention comprises: a substrate in which leads of a first group and a second group are formed; and a semiconductor chip including electrodes of a first group aligned along a first line and electrodes of a second group. At least two of the electrodes of the second group are located in each of a plurality of regions partitioned by a plurality of second lines orthogonalized with the first line, and each of the regions is a region surrounded by a pair of the second lines contacting and sandwiching a pair of the electrodes of the first group adjacent each other. The semiconductor chip is mounted on the substrate such that the electrodes of the first group face the leads of the first group and the electrodes of the second group face the leads of the second group, and each of the leads of the second group is located so as to go through leads of the first group.

According to the present invention, electrodes of the first group and second group are arranged above so as to maintain a wider pitch and avoid contacting a lead with an electrode.

In the semiconductor device, all the electrodes of the second group may be aligned along a line parallel with the first line.

In the semiconductor device, the electrodes of the second group may be arranged so as to be classified into a plurality of groups aligned along a plurality of lines parallel with the first line.

In the semiconductor device, the electrodes of the second group may include electrodes of a third and fourth groups aligned along a third and fourth lines parallel with the first line; and at least one electrode of the third group and at least one electrode of the fourth group may be arranged in each of the regions surrounded by a pair of the second lines.

In the semiconductor device, at least two of the electrodes of the third group are arranged in the each of the regions surrounded by a pair of the second lines, and at least one of the electrodes of the fourth group may be arranged in each of the regions contacting and sandwiching a pair of the electrodes of the third group as well as being surrounded by a pair of a fifth line orthogonalized with the first line in each of the regions.

In the semiconductor device, at least two of the electrodes of the third group and at least two of the electrodes of the fourth group may be arranged in a zigzag state in the each of the regions surrounded by a pair of the second lines.

In the semiconductor device, at least two of the electrodes of either the third group or the fourth group may be arranged in the each of the regions surrounded by a pair of the second lines.

In the semiconductor device, at least two of the electrodes of the third group may be arranged in the first region surrounded by a pair of the second lines sandwiching and contacting the first line and the second lines of the first group adjacent each other, at least two of the electrodes of the fourth group may be arranged in the second region surrounded by a pair of the second lines contacting and sandwiching the second electrode of the first group and the third electrodes adjacent to the second electrode.

In an electronic module of the present invention, the semiconductor device mentioned above is mounted.

In an electronic apparatus of the present invention, the above mentioned semiconductor device is installed.

A semiconductor chip of the present invention comprises: electrodes of a first group aligned with a first line, and electrodes of a second group, wherein at least two of the electrodes of the second group are located in each of a plurality of regions partitioned by a plurality of second lines orthogonalized with the first line, and each of the regions is a region surrounded by a pair of the first line contacting and sandwiching a pair of the electrodes of the first group adjacent each other. According to the present invention, electrodes of the first group and second group are arranged above so as to maintain a wider pitch and avoid contacting a lead with an electrode.

In the semiconductor device, all the electrodes of the second group may be aligned along a line parallel with the first line.

In the semiconductor device, the electrodes of the second group may be arranged so as to be classified into a plurality of groups aligned along a plurality of lines parallel with the first line.

In the semiconductor device, the electrodes of the second group may include electrodes of a third and fourth groups aligned along a third and fourth lines parallel with the first line; and at least one electrode of the third group and at least one electrode of the fourth group may be arranged in each of the regions surrounded by a pair of the second lines. At least one of the electrodes of the third group and at least one of the electrodes of the fourth group may be arranged in the each of the regions surrounded by a pair of the second lines.

In the semiconductor device, at least two of the electrodes of the third group are arranged in the each of the regions surrounded by a pair of the second lines, and at least one of the electrodes of the fourth group may be arranged in each of the regions contacting and sandwiching a pair of the electrodes of the third group as well as being surrounded by a pair of a fifth line orthogonalized with the first line in each of the regions.

In the semiconductor device, at least two of the electrodes of the third group and at least two of the electrodes of the fourth group may be arranged in a zigzag state in the each of the regions surrounded by a pair of the second lines.

In the semiconductor device, at least two of the electrodes of either the third group or the fourth group may be arranged in the each of the regions surrounded by a pair of the second lines.

In the semiconductor device, at least two of the electrodes of the third group may be arranged in the first region surrounded by a pair of the second lines sandwiching and contacting the first line and the second lines of the first group adjacent each other, at least two of the electrodes of the fourth group may be arranged in the second region surrounded by a pair of the second lines contacting and sandwiching the second electrode of the first group and the third electrodes adjacent to the second electrode.

A method of manufacturing a semiconductor device of the present invention comprises: mounting a semiconductor chip including electrodes of a first group aligned along a first line and electrodes of a second group on a substrate in which leads of a first and a second group are formed; jointing the electrodes of the first group with the leads of the first group and jointing the electrodes of the second group with the leads of the second group. At least two of the electrodes of the second group are located in each of a plurality of regions partitioned by a plurality of second lines orthogonalized with the first line, each of the regions is a region surrounded by a pair of the second lines contacting and sandwiching a pair of the electrodes of the first group adjacent each other, each of the leads of the second group is located so as to go through leads of the first group. According to the present invention, electrodes of the first group and second group are arranged above so as to maintain a wider pitch and avoid contacting a lead with an electrode.

### BRIEF DESCRIPTION OF THE DRAWINGS

FIG. 1 shows a semiconductor device of a first embodiment of the invention.

FIG. 2 is an enlarged view of an area surrounded by a dashed line of the semiconductor device shown in FIG. 1

FIG. 3 is a longitudinal cross section of the III-III line shown in FIG. 2.

FIG. 4 shows a semiconductor device of a modification of the invention.

FIG. 5 shows a semiconductor device of a second embodiment of the invention.

FIG. 6 shows a semiconductor device of a third embodiment of the invention.

FIG. 7 shows a semiconductor device of a fourth embodiment of the invention.

FIG. 8 shows an electronic module in which semiconductor devices of the embodiments are installed.

FIG. 9 shows electronic equipment having semiconductor devices of the embodiments.

FIG. 10 shows electronic equipment having semiconductor devices of the embodiments.

### DETAILED DESCRIPTION

Embodiments of the invention will now be described with reference to the accompanying drawings.

First Embodiment

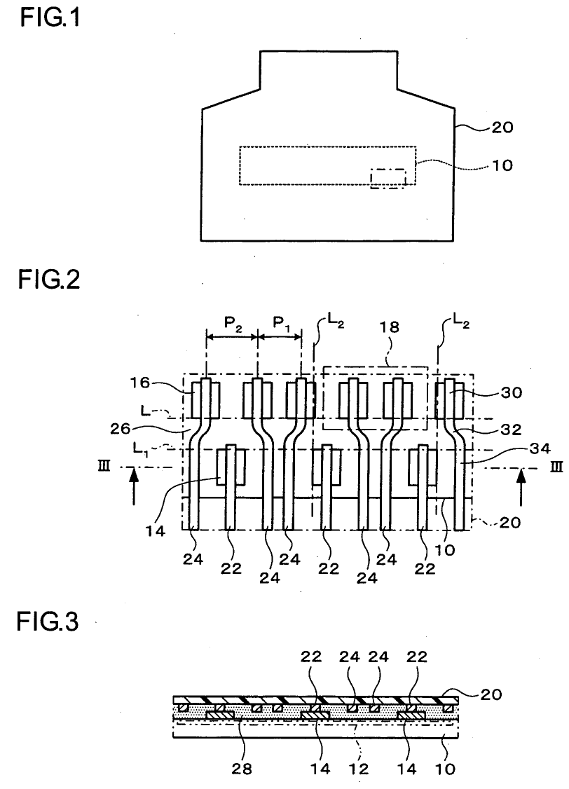

FIG. 1 is a view illustrating a semiconductor device according to the first embodiment of the invention. FIG. 2 is an enlarged view of a portion, which is surrounded by a chain line of the semiconductor device shown in FIG. 1. FIG. 3 is a cross section of III-III lines shown in FIG. 2.

A semiconductor device has a semiconductor chip 10. The semiconductor chip 10 may have a shape of a rectangle (a cuboid). An integrated circuit 12 is formed in the semiconductor chip 10. A passivation film (an electrical isolation film) not shown in the figure may be formed to cover the integrated circuit 12.

The semiconductor chip 10 includes electrodes 14 of a first group aligned along a first line L1. Electrodes 14 of a first group are aligned in a line. The first line L1 may be a line in parallel with the edge of the semiconductor chip 10 (a longer side of a rectangle). Electrodes 14 of a first group may be aligned between the first line L1 and the semiconductor chip 10. Electrodes 14 of a first group may be aligned with an equivalent pitch.

The semiconductor chip 10 includes electrodes 16 of a second group. Electrodes 16 of the second group are aligned in a line along the line L. The line L may be a line in parallel with the edge of the semiconductor chip (a longer side of a rectangle). The line L is extended in parallel with the first line L1. The line L may be located near to the center of the semiconductor chip 10 instead of the first line L1. Electrodes 16 of the second group may be aligned in the region near to the center of the semiconductor chip 10 among a pair of the regions partitioned by the line L. Electrodes 16 of the second group may be aligned with an unequal pitch. As shown in FIG. 2, Electrodes 16 of the second group may be aligned with pitches of electrodes adjacent each other like P₁, P₂ (P₁<P₂). When Electrodes 16 of the second group are segmented to more than two electrodes 16 (two in the figure), the pitch of segmented more than two electrodes 16 is P₁ and the pitch of electrodes 16 adjacent to the segmented more than two electrodes 16 is P₂.

At least two of the electrodes 16 of the second group are located in each of a plurality of regions 18 partitioned by a plurality of second lines L₂ orthogonalized with the first line L₁. Each of the regions 18 is a region surrounded by a pair of the second lines L₂ contacting and sandwiching a pair of the electrodes 14 of the first group adjacent each other.

According to the present embodiment, electrodes 14 and 16 of the first group and second group are arranged above so as to maintain a wider pitch and avoid contacting leads 22 and 24 with electrodes 14 and 16.

Electrodes 14 and 16 of the first group and second group are aligned on two sides sandwiching the region 26 between the first line L₁ and the line L. Electrodes 14 and 16 of the first group and second group may be pads or bumps thereon and composed of a metal such as a cupper or gold. Electrodes 14 and 16 of the first group and second group are electrically connected the inside of the semiconductor chip 10 and more than two of electrodes 14 and 16 of the first group and second group (not all electrodes but plural electrodes) are electrically connected to the integrated circuit 12. Electrodes 14 and 16 of the first group and second group may be formed as exposed from the passivation film not shown in the figure.

A semiconductor device has a substrate 20. The substrate 20 may be a plate or a film. The substrate 20 is made of a material of which the coefficient of thermal expansion (coefficient of linear expansion) is larger than that of the semiconductor chip 10. The substrate 20 may have low heat release since its heat conductivity is lower than that of the semiconductor chip 10. The substrate 20 may be made of a resin such as a polyimide resin or a hybrid material in which organic material like a resin with inorganic material are mixed.

The semiconductor chip 10 is mounted on the substrate 20. The semiconductor chip 10 may be mounted by a chip on film (COF). The surface of semiconductor chip 10 including electrodes 14 and 16 of the first group and the second group opposes to the substrate 20.

The leads 22 of a first group are formed on the substrate 20. The leads 22 of the first group (a part of them) may be opposed and jointed to electrodes 14 (a part of them) of the first group. The joint includes not only joint with forming eutectic crystal metal made of the above two materials, but joint enclosing conductive particles between two materials. The leads 22 of the first group are extended to the direction, which intersects (is orthogonalized, for example) with the first line L₁ as a standard for aligning electrodes 14 of the first group. The leads 22 of the first group is extended as being far from electrodes 16 (or the line L) of the second group.

The leads 24 of a second group are formed on the substrate 20. The leads 24 of the second group (a part of them) may be opposed and jointed to electrodes 16 (a part of them) of the second group. The joint includes not only joint with forming a eutectic crystal metal made of the above two materials, but joint enclosing conductive particles between two materials. The leads 24 of the second group are extended to the direction, which intersects (is orthogonalized, for example) with the first line L as a standard for aligning electrodes 16 of the second group. The leads 24 of the second group are extended to the direction close to the first line L₁ from electrodes 16 (or the line L) of the second group and intersects with the first line L₁.

The leads 24 of the second group are extended as going through electrodes 14 (or the lead 22 of the first group) of the first group. In detail, at least two (two in the figure) of the leads 24 of the second group go through a pair of electrodes 14 of the first group adjacent each other.

Each of leads 24 of the second group is formed as bent in the region 26 between the first line L₁ and the line L. Here, “bent” may be a configuration of a curve without an angle. The configuration without an angle contributes that it is uneasy to disconnect the lead 24 of the second group since stress does not concentrate into a local area even deformed. Each of leads 24 of the second group may be formed as linear 8 (without bent) except the region 26 between the first line L₁ and the line L before joining electrodes 16 on designing.

In FIG. 2, one of leads 24 of the second group adjacent to the right side of each of leads 22 of the first group is extended as bent toward the right direction of the semiconductor chip 10 (refer to FIG. 1) in the region 26. In general, one of leads 24 of the second group adjacent to each of leads 22 of the first group (adjacent to the direction of the end near the semiconductor chip among the ends of semiconductor chip 10 along with the first line L₁ and the line L) is extended as bent toward the direction of the end near the semiconductor chip 10 (refer to FIG. 1) in the region 26 between the first line L₁ and the line L. A pair of the leads located at the most outside (two leads 24 in the figure) among the at least two leads 24 of the second group is extended as bent toward the direction in which moth leads are close each other in the region 26 between the first line L₁ and the line L.

At least one of leads 22 of the first group or 24 of the second group are made of a metal like a copper. All leads 22 of the first group (or leads 24 of the second group) may be attached to the substrate 20. Otherwise, at least a part overlapped with the semiconductor chip 10 may be attached to the substrate 20. “Attached” includes not only adhered with an adhesive, but also attached directly to the substrate 20.

As shown in FIG. 3, a resin (an under filled material or an adhesive) may be put between the semiconductor chip 10 and the substrate 20. A resin 28 may bond electrodes 14 and 16 of the first and second groups as well as leads 22 and 24 of the first and second groups with pressure mutually by contraction force. The resin 28 may disperse or absorb the stress caused by different coefficients of thermal expansion between the semiconductor chip 10 and the substrate 20. Bending the leads 24 of the second group without an angle causes better fluid nature and filling of the precursor (a liquid or a paste) of the resin 28 when it is formed.

Next, a method for manufacturing a semiconductor device according to an embodiment will now be described. In the embodiment, the abovementioned semiconductor chip 10 and the substrate 30 are prepared. As shown in FIG. 2, each of leads 24 of the second group includes a first part 30, a bent part 32 and a second part 34 extended for the bent part 32. At least the second part 34 (or all) of the leads 24 of the second group is attached to the substrate 20 (attached with an adhesive or directly attached, for example). The leads 24 already have the above feature before jointing or heating process described hereafter. A pair of the leads 24 located at the most outside among the at least two leads 24 of the second group may be extended as bent toward the direction in which leads are close each other and from the first part 30 toward the second part 34 in each of the bent portion 32.

In the embodiment, the semiconductor chip 10 and the substrate 30 may be heated. The object of heating may be to harden a thermal hardening adhesive for attaching the semiconductor chip 10 and the substrate 20. Otherwise, it may be to bond electrodes 14 and 16 of the first and second groups as well as leads 22 and 24 of the first and second groups. Or it may be to perform the above both ways. The semiconductor chip 10 and the substrate 30 are expanded by heating.

In the embodiment, the semiconductor chip. 10 is mounted on the substrate 30. Any of the electrodes 14 of the first group (a part of them) are bonded to any of leads 22 (a part of them) of the first group. Any of the electrodes 16 of the second group (a part of them) are bonded to any of leads 24 (a part of them) of the second group (referrer to FIG. 2). The bonding may be performed with heating. Or preheating may be preformed before bonding and bonding may be performed with additional heating.

At the time of bonding, the leads 22 of the first group are extended toward the direction opposed to electrodes 16 of the second group from the bonded portion with electrodes 14 of the first group. The first part 30 of the leads 24 of the second group opposes any of the electrodes 16 of the second group. The bent portion 32 is placed in the region 26 between the first line L₁ and the line L. The second part 34 of the leads 24 of the second go through the electrodes 14 of the first group.

At the time of bonding, the bent portion 32 in one of leads 24 of the second group adjacent to each of leads 22 of the first group and adjacent to the direction of the end near the semiconductor chip among the ends of semiconductor chip 10 along with the first line L₁ and the line L is extended as bent toward the direction from the first part 30 to the second part 34 and the end near the semiconductor chip 10 (the right direction in FIG. 1 and FIG. 2). In detail, at least two (two in the figure) of the leads 24 of the second group are placed so as to go through a pair of electrodes 14 of the first group adjacent each other. All other details have been already explained in the above.

The semiconductor device according to the present embodiment can be manufactured by the method including the above process. Furthermore, when different coefficients of thermal expansion (coefficients of linear expansion for example) between the semiconductor chip 10 and the substrate 20, a method of manufacturing the semiconductor device may include contraction of the semiconductor chip 10 and the substrate 20 with heat releasing.

The method of manufacturing the semiconductor device according to the present embodiment may include a process that is introduced from the above explanation of the semiconductor device. The semiconductor device according to the present embodiment may include a structure obtained by the above process.

According to the present embodiment, the lead 24 of the second group is bent so that the bent portion 32 is further bent more easily. The bent portion 32 is placed in the region 26 between the first line L₁ and the line L region. This region 26 is a region between electrodes 14 and 16 of the first and the second groups so that it is uneasy to contact electrodes 14 with electrodes 16 even the lead 24 is bent. Therefore, contact of the leads 24 with the electrodes 14 and 16 can be avoided thereby.

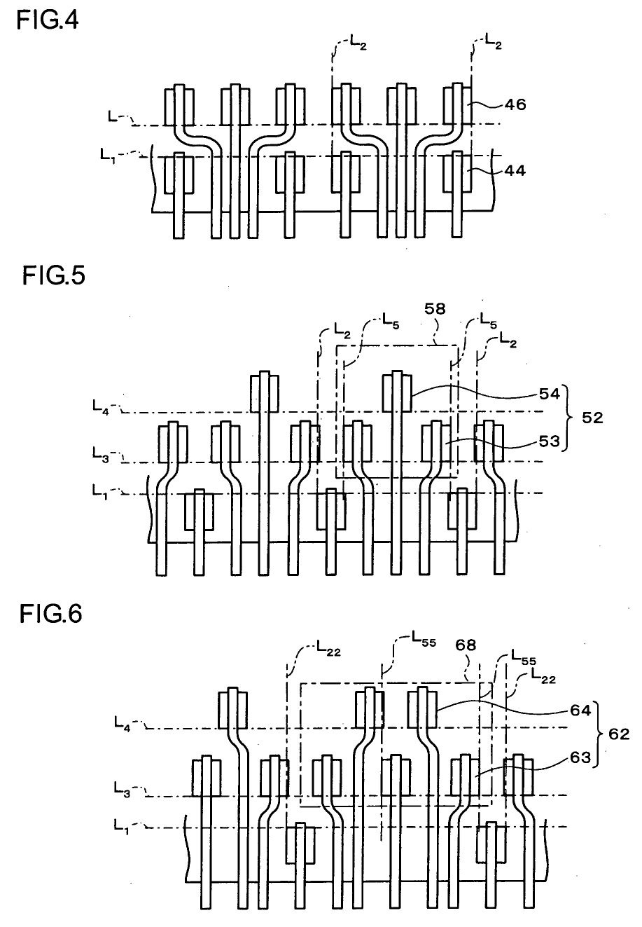

FIG. 4 shows modification of a semiconductor device according to the embodiment. Terms used in the first embodiment are also applied to this embodiment as the same meaning (except numerical reference). In the modification, at least two (three in the figure) of electrodes 46 of the second group is placed so as to be sandwiched and contact by a pair of the second lines L₂. A pitch (or a period) of a pair of electrodes 44 of the first group may be equal to a pitch (or a period) of a pair of electrodes 46 of the second group which are the most far way.

The aforementioned details in the previous embodiment are applied to the semiconductor device and manufacturing method thereof and the semiconductor chip of the modification except the above explanation.

Second Embodiment

FIG. 5 shows a semiconductor device of a second embodiment of the invention. Terms used in the first embodiment is also applied to the second embodiment as the same meaning (except reference numeral). In the embodiment, electrodes 52 of the second group are arranged so as to be classified into electrodes of a plurality of groups (electrodes 53 and 54 of the third and fourth groups for example) along a plurality of lines in parallel with the first line L₁ (the third and fourth lines L₃ and L₄ for example) .

At least one, and at least two (two in the figure) electrodes 53 of the third group are arranged within the region 58 sandwiched by a pair of the second lines L₂. Within the region 58, at least one (one in FIG. 5) of electrodes 54 of the fourth group is arranged. At least one of the electrodes 54 of the fourth group is arranged in each of the regions 58 contacting a pair of the electrodes 53 of the third group with sandwiching these electrodes as well as being surrounded by a pair of a fifth line L₅ orthogonalized with the first line L₁.

The aforementioned details in the first embodiment and its modification are applied to the semiconductor device and manufacturing method thereof and the semiconductor chip of the present embodiment except the above explanation.

Third Embodiment

FIG. 6 shows a semiconductor device of a third embodiment of the invention. Terms used in the first and second embodiments are also applied to the third embodiment as the same meaning (except reference numerals). In the embodiment, electrodes 62 of the second group are arranged so as to be classified into electrodes of a plurality of groups (electrodes 63 and 64 of the third and fourth groups for example) along a plurality of lines in parallel with the first line L₁ (the third and fourth lines L₃ and L₄ for example).

At least one, and at least two (four in the figure) electrodes 63 of the third group are arranged within each of the regions 68 sandwiched by a pair of the second lines L₂₂. Within each of the regions 68, at least one (two in FIG. 6) of electrodes 64 of the fourth group is arranged. At least one of the electrodes 64 of the fourth group is arranged in each of the regions 68 contacting a pair of the electrodes 63 of the third group with sandwiching these electrodes as well as being surrounded by a pair of a fifth line L₅₅ orthogonalized with the first line L₁.

In the embodiment, at least two of the electrodes 63 of the third group and at least two of the electrodes 64 of the fourth group are arranged in a zigzag state in the each of the regions 68.

The aforementioned details in the first embodiment, its modification and the second embodiment are applied to the semiconductor device and manufacturing method thereof and the semiconductor chip of the present embodiment except the above explanation.

Fourth Embodiment

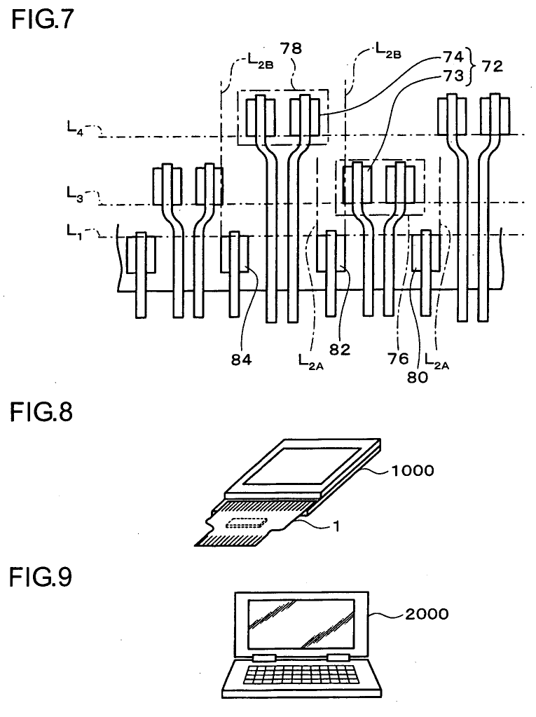

FIG. 7 shows a semiconductor device of a fourth embodiment of the invention. Terms used in the first, second and third embodiments are also applied to the present embodiment as the same meaning (except reference numerals). In the embodiment, electrodes 72 of the second group are arranged so as to be classified into electrodes of a plurality of groups (electrodes 73 and 74 of the third and fourth groups for example) along a plurality of lines in parallel with the first line L1 (the third and fourth lines L₃ and L₄ for example).

At least two of electrodes 73 of the second group are arranged in the first region 76 surrounded by a pair of the second lines L_{2A}, if the second lines L_{2A} is drawn contacting and sandwiching the first and second electrodes 80 and 82 of the first group adjacent each other. Electrodes 74 of the fourth group are not arranged in the first region 76.

At least two of electrodes 74 of the fourth group are arranged in the second region 78 surrounded by a pair of the second lines L_{2B}, if the second lines L_{2B} is drawn contacting and sandwiching the second electrode 82 and third electrode 84 of the first group adjacent each other. Electrodes 73 of the third group are not arranged in the second region 78.

The aforementioned details in the first embodiment, its modification the second and third embodiments are applied to the semiconductor device and manufacturing method thereof and the semiconductor chip of the present embodiment except the above explanation.

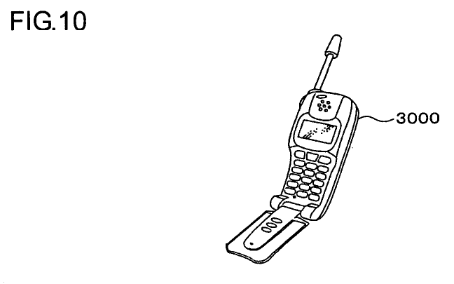

FIG. 8 shows an electronic module 1000 (a liquid crystal module for example) in which the semiconductor device 1 of the above mentioned embodiments is installed. As electronic equipment having the semiconductor device, FIG. 9 shows a note type personal computer 2000. FIG. 10 shows a cellar phone 3000.

It should be noted that the present invention is not limited to the above-mentioned embodiments, and various changes and modifications can be made within the spirit and scope of the invention. For example, the present invention includes substantially the same structure (including the structure with the same functions, methods, and results and the structure with the same goals and results) as the structure of the above-mentioned embodiments. The present invention also includes other structures in which non-essential elements of the above-mentioned embodiments are substituted. The present invention also includes the structures that can achieve the same effects or the same goals as those achieved by the above-mentioned embodiments. Moreover, the present invention includes other structures in which known methods and techniques are incorporated into the above-mentioned embodiments. Moreover, the present invention includes structures in which any of technical items explained in the above embodiments are limitedly excluded. Moreover, the present invention includes structures in which any of well-known technologies are limitedly excluded from the above-mentioned embodiments.

1. A semiconductor device comprising:
a substrate in which leads of a first group and a second group are formed;
a semiconductor chip including electrodes of a first group aligned along a first line and electrodes of a second group;
wherein at least two of the electrodes of the second group are located in each of a plurality of regions partitioned by a plurality of second lines orthogonalized with the first line and each of the regions is a region surrounded by a pair of the second lines contacting and sandwiching a pair of the electrodes of the first group adjacent each other, and
wherein the semiconductor chip is mounted on the substrate such that the electrodes of the first group face the leads of the first group and the electrodes of the second group face the leads of the second group; and
each of the leads of the second group is located so as to go through leads of the first group.

2. A semiconductor device according to claim 1, wherein all the electrodes of the second group are aligned along a line parallel with the first line.

3. A semiconductor device according to claim 1, wherein the electrodes of the second group are arranged so as to be classified into a plurality of groups aligned along a plurality of lines parallel with the first line.

4. A semiconductor device according to claim 3, wherein the electrodes of the second group includes electrodes of a third and fourth groups aligned along a third and fourth lines parallel with the first line; and
at least one electrode of the third group and at least one electrode of the fourth group are arranged in each of the regions surrounded by a pair of the second lines.

5. A semiconductor device according to claim 4, wherein at least two of the electrodes of the third group are arranged in each of the regions surrounded by a pair of the second lines and at least one of the electrodes of the fourth group is arranged so as to contact and sandwich a pair of the electrodes of the third group as well as being surrounded by a pair of fifth lines orthogonalized with the first line in each of the regions.

6. A semiconductor device according to claim 4, wherein at least two of the electrodes of the third group and at least two of the electrodes of the fourth group are arranged in a zigzag state in the each of the regions surrounded by a pair of the second lines.

7. A semiconductor device according to claim 4, wherein at least two of the electrodes of either the third group or the fourth group are arranged in the each of the regions surrounded by a pair of the second lines.

8. A semiconductor device according to claim 7, wherein at least two of the electrodes of the third group are arranged in a first region surrounded by a pair of the second lines sandwiching the first line and the second lines of the first group adjacent each other, and at least two of the electrodes of the fourth group are arranged in a second region surrounded by a pair of the second lines contacting and sandwiching the second electrode of the first group and the third electrodes adjacent to the second electrodes.

9. An electronic module, including the semiconductor device according to claim 1.

10. An electronic apparatus including the semiconductor device according to claim 1.

11. A semiconductor chip comprising:
electrodes of a first group aligned along a first line; and
electrodes of a second group, wherein at least two of the electrodes of the second group are located in each of a plurality of regions by a plurality of second lines orthogonalized with the first line, and each of the regions is a region surrounded by a pair of the second lines contacting and sandwiching a pair of the electrodes of the first group adjacent each other.

12. A semiconductor device according to claim 11, wherein all the electrodes of the second group are aligned along a line parallel with the first line.

13. A semiconductor chip according to claim 11, wherein the electrodes of the second group are arranged along a plurality of lines aligned in parallel with the first line.

14. A semiconductor chip according to claim 13, wherein the electrodes of the second group includes electrodes of a third and fourth groups aligned along a third and fourth lines in parallel with the first line; and
at least one electrode of the third group and at least one electrode of the fourth group are arranged in each of regions surrounded by a pair of the second lines.

15. A semiconductor chip according to claim 14, wherein at least two of the electrodes of the third group are arranged in the each of the regions surrounded by a pair of the second lines, and at least one of the electrodes of the fourth group is arranged so as to contact and sandwich a pair of the electrodes of the third group as well as being surrounded by a pair of a fifth line orthogonalized with the first line in each of the regions.

16. A semiconductor chip according to claim 14, wherein at least two of the electrodes of the third group and at least two of the electrodes of the fourth group are arranged in a zigzag state in the each of the regions surrounded by a pair of the second lines.

17. A semiconductor chip according to claim 14, wherein at least two of the electrodes of either the third group or the fourth group are arranged in the each of the regions surrounded by a pair of the second lines.

18. A semiconductor chip according to claim 17, wherein at least two of the electrodes of the third group are arranged in the first region surrounded by a pair of the second lines sandwiching and contacting the first line and the second lines of the first group adjacent each other, and at least two of the electrodes of the fourth group are arranged in the second region surrounded by a pair of the second lines contacting and sandwiching the second electrode of the first group and the third electrodes adjacent to. the second electrode.

19. A method of manufacturing a semiconductor device comprising:
mounting a semiconductor chip including electrodes of a first group aligned along a first line and electrodes of a second group on a substrate in which leads of a first and a second group are formed;
jointing the electrodes of the first group with the leads of the first group and jointing the electrodes of the second group with the leads of the second group, wherein at least two of the electrodes of the second group are located in each of a plurality of regions partitioned by a plurality of second lines orthogonalized with the first line, each of the regions is a region surrounded by a pair of the second lines contacting and sandwiching a pair of the electrodes of the first group adjacent each other, and each of the leads of the second group is located so as to go through leads of the first group.
